(19) United States
(12) Patent Application Publication
(10) Pub. No.: US 2019/0138359 A1
(43) Pub. Date: May 9, 2019

(54) REALTIME CRITICAL PATH-OFFLOADED DATA PROCESSING APPARATUS, SYSTEM, AND METHOD

(71) Applicant: Intel Corporation, Santa Clara, CA (US)

(72) Inventors: Madhusudhan Rangarajan, Portland, OR (US); Nagasubramanian Gurumoorthy, Portland, OR (US); Robert Cone, Portland, OR (US); Rajesh Poornachandran, Portland, OR (US); Kartik Ananthanarayanan, Portland, OR (US); Rebecca Weekly, Redwood City, CA (US)

(73) Assignee: Intel Corporation, Santa Clara, CA (US)

(21) Appl. No.: 16/113,872

(22) Filed: Aug. 27, 2018

(51) Int. Cl. G06F 9/50; G06F 9/445; G06F 3/06

(52) U.S. Cl. CPC G06F 9/5027; G06F 9/445; G06F 3/0608; G11C 13/0004; G06F 3/0661; G06F 3/0673; G06F 2209/509; G06F 3/0641

(57) ABSTRACT

Devices, systems, and methods for offloading data service operations from an application critical path are disclosed. A storage service control apparatus can include a compute resource interface configured to communicatively couple to a compute resource, a memory interface configured to communicatively couple to a memory resource, an out of band (oob) channel interface configured to communicatively couple to an oob channel, and a data service controller communicatively coupled to the oob channel interface. The data service controller is configured to identify a data service operation to be performed by the compute resource on data stored in the memory resource, load a data service agent configured to facilitate the data service operation, and perform the data service operation on the data to generate serviced data via the data service agent over the oob channel by an oob compute resource, thus freeing the compute resource from performing the data service operation.

### BACKGROUND

Computer systems operate by executing instruction sequences that form a computer program. These instructions sequences are stored in a memory subsystem, along with any data operated on by the instructions, both of which are retrieved as necessary by a processor, such as a central processing unit (CPU). Various computer components can affect the performance a system, such as the CPU, system and storage memory, memory subsystem architecture, and the like, for example. With ever-increasing needs for higher computer system performance, component performance has become an important factor in improving system performance. The speed of CPUs, for example, has increased at a much faster rate compared to the memory subsystems upon which they rely for data and instruction code, and as such, memory subsystems can be a significant performance bottleneck. While one solution to this bottleneck would be to primarily use in a computer system only very fast memory, such as static random-access memory, the cost of such memory would be prohibitive. In order to balance cost with system performance, memory subsystem architecture is typically organized in a hierarchical structure, with faster expensive memory operating near the processor at the top, slower less expensive memory operating as storage memory at the bottom, and memory having an intermediate speed and cost, operating in the middle of the memory hierarchy.

### BRIEF DESCRIPTION OF THE DRAWINGS

FIG. 1 illustrates a block diagram of a memory subsystem in accordance with an example embodiment;

FIG. 2 illustrates a block diagram of a memory controller including a data services controller in accordance with an example embodiment;

FIG. 3 illustrates a block diagram of an integrated CPU package including a memory controller and a data services controller in accordance with an example embodiment;

FIG. 4 illustrates a block diagram of a network system in accordance with an example embodiment; and

FIG. 5 illustrates a method of performing a data service operation on hot data in accordance with an example embodiment.

### DESCRIPTION OF EMBODIMENTS

Although the following detailed description contains many specifics for the purpose of illustration, a person of ordinary skill in the art will appreciate that many variations and alterations to the following details can be made and are considered included herein. Accordingly, the following embodiments are set forth without any loss of generality to, and without imposing limitations upon, any claims set forth. It is also to be understood that the terminology used herein is for describing particular embodiments only, and is not intended to be limiting. Unless defined otherwise, all technical and scientific terms used herein have the same meaning as commonly understood by one of ordinary skill in the art to which this disclosure belongs. Also, the same reference numerals in appearing in different drawings represent the same element. Numbers provided in flow charts and processes are provided for clarity in illustrating steps and operations and do not necessarily indicate a particular order or sequence.

Furthermore, the described features, structures, or characteristics can be combined in any suitable manner in one or more embodiments. In the following description, numerous specific details are provided, such as examples of layouts, distances, network examples, etc., to provide a thorough understanding of various embodiments. One skilled in the relevant art will recognize, however, that such detailed embodiments do not limit the overall concepts articulated herein, but are merely representative thereof. One skilled in the relevant art will also recognize that the technology can be practiced without one or more of the specific details, or with other methods, components, layouts, etc. In other instances, well-known structures, materials, or operations may not be shown or described in detail to avoid obscuring aspects of the disclosure.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open-ended term in this written description, like “comprising” or “including,” it is understood that direct support should be afforded also to “consisting essentially of” language as well as “consisting of” language as if stated explicitly and vice versa.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of phrases including “an example” or “an embodiment” in various places throughout this specification are not necessarily all referring to the same example or embodiment.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

As used herein, comparative terms such as “increased,” “decreased,” “better,” “worse,” “higher,” “lower,” “enhanced,” and the like refer to a property of a device, component, or activity that is measurably different from other devices, components, or activities in a surrounding or adjacent area, in a single device or in multiple comparable devices, in a group or class, in multiple groups or classes, or as compared to the known state of the art. For example, a data region that has an “increased” risk of corruption can refer to a region of a memory device which is more likely to have write errors to it than other regions in the same memory device. A number of factors can cause such increased risk, including location, fabrication process, number of program pulses applied to the region, etc.

An initial overview of embodiments is provided below, and specific embodiments are then described in further detail. This initial summary is intended to aid readers in understanding the disclosure more quickly and is not intended to identify key or essential technological features, nor is it intended to limit the scope of the claimed subject matter.

In general, application developers tend to not include various types of data service operations in applications that are not specific to the execution of the application. For example, “hot data” is data that is in high demand within a given system, and thus can be frequently accessed, transferred, etc. Compression of hot data could improve the transfer and ephemeral storage of such data, however the compression would generally need to be performed by the processor running the application, which has the drawback of interrupting the critical path of the application for the duration of the compression process. In other words, application developers do not typically compress hot data because doing so slows down critical data access time. Due to traditionally small-sized application data sets, however, the need for data service operations such as hot data compression has been minimal. As the size of application data sets continue to increase, however, performing such data service operations can beneficially impact the performance of many types of computation, network, and data-intensive systems; however, the increased computational load on the processor running the application, along with the interruption to the critical path execution of the application, will likely offset any benefits provided by performing the data service operation.

The present disclosure provides a technological solution to these challenges that allows such data service operations to be performed without significant involvement from a processor or compute resource running the application. Specifically, such data service operations can be offloaded to a secondary compute resource for processing, in some cases over an out-of-band (oob) channel. By performing such data service operations (i.e., data service tasks) via the secondary compute resource, the processor (or primary compute resource) can be released to continue execution of the application, move onto another application task, or the like. Such an implementation thus allows beneficial data services to be performed that would normally interrupt the critical path without significant negative performance impact on the compute resource, computation system, network, or the like.

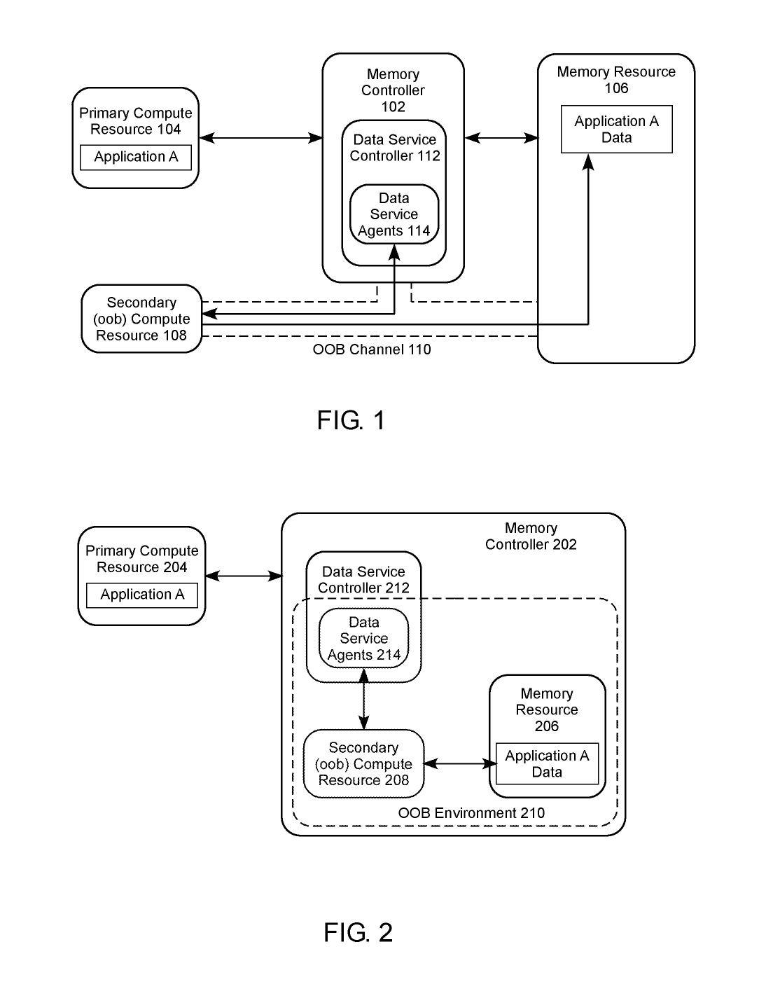

FIG. 1 shows one general example of a system including a memory controller 102 configured to receive data requests (e.g., read data requests and write data requests) from a primary compute resource 104. The primary compute resource 104 is shown executing Application A, which is associated with Application A data located in a memory resource 106. As such, the memory controller 102 receives a data request from the primary compute resource 104 that is associated with the Application A data. The memory controller 102 initiates a data operation to perform the data request on the Application A data, and then depending on the type of data request, generally either returns requested data or an acknowledgment that the data request has been filled. In cases where a data service operation is to be performed on the Application A data, an indication of the data service operation can be associated with the data request, requested or generated apart from the primary compute resource 104, determined locally in the memory controller 102 or in circuitry associated with the memory controller 102, or the like. The primary compute resource 104 would generally be tasked with the processing needed to perform the data service operation, regardless of the origination of the data service request. Performance of data service operations on the Application A data, however, would interrupt the Application A critical execution path, or in other words, would cause the primary compute resource 104 to pause execution of Application A while performing the data service operation.

In order to avoid or otherwise minimize interruptions of the critical path, the data service operation can be offloaded to a secondary compute resource 108, in some cases over an oob channel 110. FIG. 1 shows one example implementation including a data service controller 112 and a plurality of associated data service agents 114. The data service agents 114 are configured to facilitate various data service operations or subtasks of data service operations, to provide support to other data service agents, to gather system data for use by other data service agents, to make data service operation decisions, to schedule data service operations and subtasks thereof, or the like. As such, in one implementation example the memory controller 102 can notify the data service controller 112 of a data service operation to be performed on Application A data. The data service controller 112 can load one or more data service agents 114 to perform the data service operation using the secondary compute resource 108 over the oob channel 110. In some cases, the data service operation can be performed on data resident in the memory resource 106, where the data will be further maintained in the memory resource 106 for further use in the execution of Application A by the primary compute resource 104. In other cases, the data service operation can be performed on the Application A data resident in the memory resource 106 prior to, or as a support service of, moving the Application A data to a storage resource. In either case, the primary compute resource 104 is thus released to continue execution of Application A or to move on to a different process thread.

The memory controller 102 can be implemented according to any number of designs. For example, the memory controller 102 can be integrated on chip or on package with the primary compute resource 104, within an uncore portion of a processor package, or in a structure or component separate from the processor package, such as, for example, in a Northbridge, a memory device, or the like. In some examples, the memory controller can be included in a network node separate from a node that includes the primary compute resource, as a component of a network interface controller (NIC) communicatively coupled to other network nodes, a distinct memory controller, a memory pool controller (MPC) for a shared memory pool of disaggregated memory devices, or the like. The specific implementation of the memory controller 102 can vary depending on a number of factors, but in most cases a memory controller includes a frontend and a backend. At a very general level, the frontend includes a host interface to the various communication buses that provide communication between the memory controller and the host, or in this case, the primary compute resource. The host interface can include a series of request buffers to queue incoming data requests and any associated write data, and a series of response buffers to queue outgoing data request acknowledgements and any associated read data. The series of request buffers can be multiplexed (muxed) into a memory mapping unit that decodes the memory address associated with the data request into a physical address that allows the data to be accessed by the memory controller. From there the data requests and the associated physical addresses can be passed to an arbiter, which arbitrates the data requests into a specific order and sends them to a command generator in the backend of the memory controller. The command generator generates the appropriate memory access commands to access the memory location of the requested data, and either write data to or read data from, that memory location. These memory access commands are sent through a memory interface to the memory resource to access the data location. Returning acknowledgements, along with any requested read data, is sent through the memory interface to the series of response buffers to fill each memory request.

Similarly, the primary compute resource 104 can be implemented according to any number of designs. For example, a primary compute resource can be a processor, such as a single processor or multiple processors, including single core processors and multi-core processors. It is noted that a processor can include any number of processor designs and/or configurations, nonlimiting examples of which can include general purpose processors, specialized processors such as central processing units (CPUs), graphics processing units (GPUs), digital signal processors (DSPs), microcontrollers (MCUs), microprocessors, embedded controllers (ECs), embedded processors, field programmable gate arrays (FPGAs), network processors and pooled network compute resources, hand-held or mobile processors, application-specific instruction set processors (ASIPs), application-specific integrated circuit (ASIC) processors, co-processors, and the like as well as other types of specialized processors, including base band processors used in transceivers to send, receive, and process wireless communications. Additionally, a processor can be packaged in numerous configurations, which is not limiting. For example, a processor can be packaged in a common processor package, a multi-core processor package, a system-on-chip (SoC) package, a system-in-package (SiP) package, a system-on-package (SOP) package, and the like. In some examples, a primary compute resource can be included in a network node, either along with or in a separate node from a memory controller. The node including a primary compute resource can be any type of node, such as a memory and/or storage node, a compute node as part of a compute pool of discrete compute resources, or the like. In some examples a primary compute resource can be a virtual machine.

The data service controller 112 and the one or more data service agents 114 can perform data service operations at any level of the memory hierarchy, including storage memory, system memory, cache memory, or the like. In some cases, the data service operations function, at any hierarchical memory level, on disaggregated memory resources. In one example, the memory resource can be system memory, or in other words, memory that is exposed in the system address space to the operating system. Depending on the memory media, system memory can be volatile memory, nonvolatile memory (NVM), or persistent memory. Volatile memory is a memory medium that requires power to maintain the state of data stored by the medium. Volatile memory can include any type of volatile memory, nonlimiting examples of which can include random access memory (RAM), such as static random-access memory (SRAM), dynamic random-access memory (DRAM), synchronous dynamic random-access memory (SDRAM), and the like, including combinations thereof. SDRAM memory can include any variant thereof, such as single data rate SDRAM (SDR DRAM), double data rate (DDR) SDRAM, including DDR, DDR2, DDR3, DDR4, DDR5, and so on, described collectively as DDRx, and low power DDR (LPDDR) SDRAM, including LPDDR, LPDDR2, LPDDR3, LPDDR4, and so on, described collectively as LPDDRx. In some examples, DRAM complies with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209B for LPDDR SDRAM, JESD209-2F for LPDDR2 SDRAM, JESD209-3C for LPDDR3 SDRAM, and JESD209-4A for LPDDR4 SDRAM (these standards are available at www.jedec.org; DDR5 SDRAM is forthcoming). Such standards (and similar standards) may be referred to as DDR-based or LPDDR-based standards, and communication interfaces that implement such standards may be referred to as DDR-based or LPDDR-based interfaces. In one specific example, the volatile memory can be DRAM. In another specific example, the volatile memory can be DDRx SDRAM. In yet another specific aspect, the volatile memory can be LPDDRx SDRAM.

In another example, a memory resource can utilize NVM, which is a memory medium that does not require power to maintain the state of data stored by the medium. NVM has traditionally been used for the task of data storage, or long-term persistent storage, but new and evolving memory technologies allow the use of some NVM technologies in roles that extend beyond traditional data storage. One example of such a role is the use of NVM as main or system memory. Nonvolatile system memory (NVMsys) can combine data reliability of traditional storage with low latency and high bandwidth performance, having many advantages over traditional volatile memory, such as high density, large capacity, lower power consumption, and reduced manufacturing complexity, to name a few. Byte-addressable, write-in-place NVM such as three-dimensional (3D) cross-point memory, for example, can operate as byte-addressable memory similar to dynamic random-access memory (DRAM), or as block-addressable memory similar to NAND flash. In other words, such NVM can operate as system memory or as persistent storage memory (NVMstor). When used as system memory, such byte-addressable, write-in-place NVM can function as persistent system memory or as non-persistent system memory similar to volatile system memory. For example, data resident in such system memory can be discarded or otherwise rendered unreadable when power to the NVMsys is interrupted, thus allowing the NVMsys to function as non-persistent memory. NVMsys also allows increased flexibility in data management by providing non-volatile, low-latency memory that can be located closer to a processor in a computing device. In some examples, NVMsys can reside on a DRAM bus, such that the NVMsys can provide ultra-fast DRAM-like access to data. NVMsys can also be useful in computing environments that frequently access large, complex data sets, and environments that are sensitive to downtime caused by power failures or system crashes.

General nonlimiting examples of NVM can include single or multi-level phase change memory (PCM), such as chalcogenide glass PCM, planar or 3D PCM, cross-point array memory, including 3D cross-point memory, non-volatile dual in-line memory module (NVDIMM)-based memory, such as flash-based (NVDIMM-F) memory, flash/DRAM-based (NVDIMM-N) memory, persistent memory-based (NVDIMM-P) memory, 3D cross-point-based NVDIMM memory, resistive RAM (ReRAM), including metal-oxide- or oxygen vacancy-based ReRAM, such as HfO2-, Hf/HfOx-, Ti/HfO2-, TiOx-, and TaOx-based ReRAM, filament-based ReRAM, such as Ag/GeS2-, ZrTe/Al2O3-, and Ag-based ReRAM, programmable metallization cell (PMC) memory, such as conductive-bridging RAM (CBRAM), silicon-oxide-nitride-oxide-silicon (SONOS) memory, ferroelectric RAM (FeRAM), ferroelectric transistor RAM (Fe-TRAM), anti-ferroelectric memory, polymer memory (e.g., ferroelectric polymer memory), magnetoresistive RAM (MRAM), write-in-place non-volatile MRAM (NVMRAM), spin-transfer torque (STT) memory, spin-orbit torque (SOT) memory, nanowire memory, electrically erasable programmable read-only memory (EEPROM), nanotube RAM (NRAIVI), other memristor- and thyristor-based memory, spintronic magnetic junction-based memory, magnetic tunneling junction (MTJ)-based memory, domain wall (DW)-based memory, and the like, including combinations thereof. The term “memory device” can refer to the die itself and/or to a packaged memory product. NVM can be byte addressable write-in-place memory. In some examples, NVM can comply with one or more standards promulgated by the Joint Electron Device Engineering Council (JEDEC), such as JESD21-C, JESD218, JESD219, JESD220-1, JESD223B, JESD223-1, or other suitable standard (the JEDEC standards cited herein are available at www.jedec.org). In one specific example, the NVM can be 3D cross-point memory.

Various different types and configurations of secondary compute resources are contemplated, and any design, type, implementation, or the like, of compute resource capable of performing data service operations over an oob channel or within an oob environment is considered to be within the present scope. For example, a secondary compute resource can be a processor, such as a single processor or multiple processors, including single core processors and multi-core processors. It is noted that a processor can include any number of processor designs and/or configurations, nonlimiting examples of which can include general purpose processors, specialized processors such as central processing units (CPUs), graphics processing units (GPUs), digital signal processors (DSPs), microcontrollers (MCUs), microprocessors, embedded controllers (ECs), embedded processors, field programmable gate arrays (FPGAs), network processors and pooled network compute resources, hand-held or mobile processors, application-specific instruction set processors (ASIPs), application-specific integrated circuit (ASIC) processors, co-processors, and the like as well as other types of specialized processors, including base band processors used in transceivers to send, receive, and process wireless communications. Additionally, a processor can be packaged in numerous configurations, which is not limiting. For example, a processor can be packaged in a common processor package, a multi-core processor package, a system-on-chip (SoC) package, a system-in-package (SiP) package, a system-on-package (SOP) package, and the like. In some examples, the secondary compute resource can be included in a network node, either along with or in a separate node from either of the primary compute resource and/or the memory controller. The node including a secondary compute resource can be any type of node, such as a memory and/or storage node, a compute node as part of a compute pool of discrete compute resources, or the like. In some examples a secondary compute resource can be a virtual machine.

The terms “oob channel” and “oob environment” can be used interchangeably and can include any communication channel or environment that is out-of-band from the critical path of the execution of the application. This can include a channel that is located apart from the critical path channel, including oob channels that are operationally the same but physically different from the critical path channel and that are operationally different but physically the same as the critical path channel. In other examples, an oob channel can include a portion of the communication channel carrying the critical path that has been operationally isolated from the critical path. Various nonlimiting examples of potentially useful oob channels can include trusted execution environments (TEEs), isolated segments of a data bus, a communication fabric, a network fabric, or the like.

FIG. 2 shows an example implementation of a memory controller 202 configured to receive data-related communications (data requests) from a primary compute resource 204. The primary compute resource 204 is shown executing Application A, which is associated with Application A data within a memory resource 206 located in the memory controller 202. As such, the memory controller 202 receives a data request from the primary compute resource 204 that is associated with the Application A data. The memory controller 202 initiates a data operation to fill the data request on the Application A data, and then depending on the type of data request, generally either returns requested data or an acknowledgment that the data request has been filled. A data service operation to be performed on Application A data can be offloaded to a secondary compute resource 208 located within or near the memory controller 202. Thus, a data service controller 212 can load one or more of a plurality of associated data service agents 214 to perform the data service operation using the secondary compute resource 208 within a local oob environment 210 within the memory controller 202. In one specific example, the memory resource 206 can be SRAM. In some examples, the memory controller 202 can be an integrated memory controller and thus reside on the same die as the primary compute resource 204.

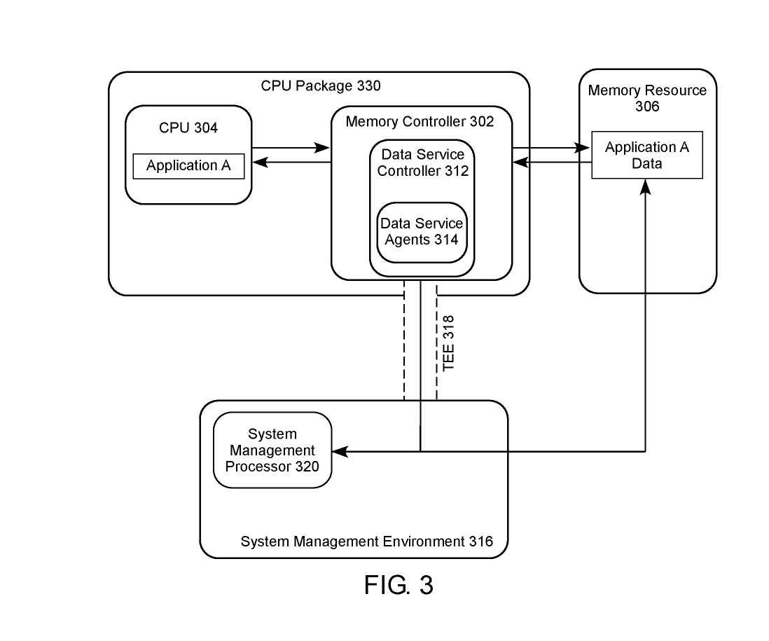

FIG. 3 illustrates another example implementation of a system including a memory controller 302 and a CPU 304 integrated on a common CPU package 330. The CPU 304 is shown executing Application A, which is associated with Application A data located in a memory resource 306. As such, the memory controller 302 receives a data request from the CPU 304 associated with the Application A data. The memory controller 302 initiates a data operation to fill the data request on the Application A data, and then depending on the type of data request, generally either returns requested data or an acknowledgment that the data request has been filled. In order to avoid or otherwise minimize interruptions of the critical path, a data service operation to be performed on Application A data can be offloaded to a secondary compute resource such as a system management processor 320 in a system management environment 316. More specifically, the memory controller 302 can notify the data service controller 312 of a data service operation to be performed on Application A data. The data service controller 312 can load one or more data service agents 314 to perform the data service operation. The data service agents 314 contact the system management processor 320 within the secure system management environment 316 through a trusted execution environment 318. The system management processor 320 is then tasked with performing the data service operation on the Application A data in memory resource 306, in a memory local to the system management environment 316, or the like. Processing by the system management processor 320 thus releases the CPU 304 to continue execution of Application A or to move on to a next process thread. Various system management environments are contemplated, one nonlimiting example of which can include Intel® Corporation's manageability engine (ME).

The presently disclosed technology can additionally provide benefits to networking, data service, and cloud computing environments, to name a few. In such environments, computation, memory, and storage resources are trending toward greater levels of disaggregation, both within and between resource types. The management of disaggregated resources, and in particular the compression of disaggregated data, can have an impact on the efficiency and performance of the environment. For example, the much larger data sets enabled by new memory technologies benefit from greater levels of disaggregation and compression provided the associated computation resource bottleneck of performing the necessary processing can be avoided or minimized. As has been described, the present technology provides a solution by performing such processing using a different computation resource through an oob channel or environment.

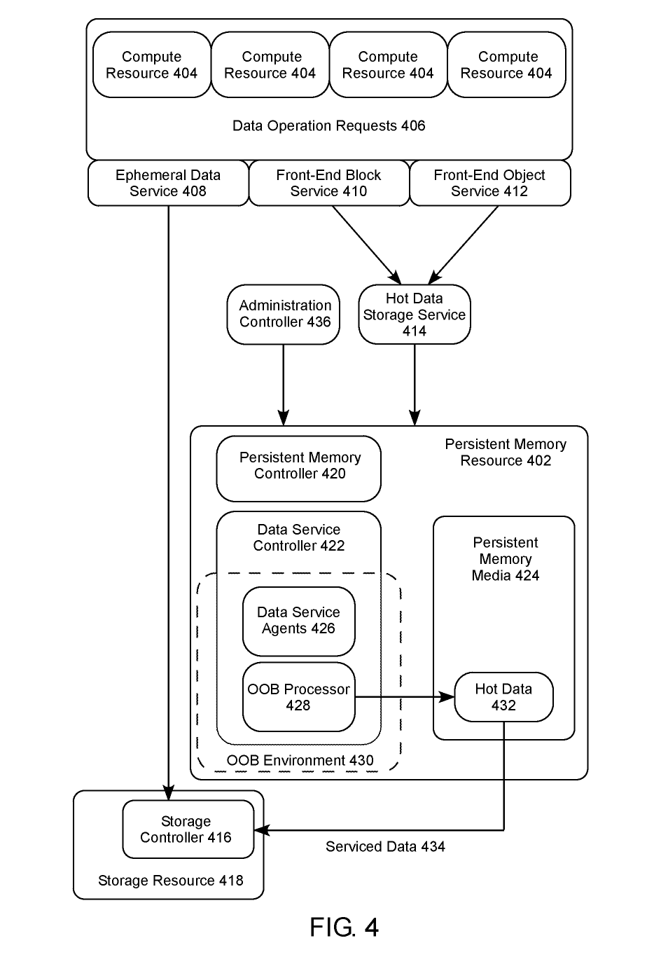

FIG. 4 shows one example of a system including a persistent memory resource 402, which can be a network node, a component of a network node, or the like. The persistent memory resource 402 can include a persistent memory controller 420, persistent memory media 424, and a data service controller 422. The system further includes a plurality of compute resources 404, which can include network compute nodes, processors, virtual machines (VMs), and the like. This plurality of compute resources 404 generates a collection of data operation requests 406 that can vary depending on the nature of the associated data, the type of data operation request, and the like. In some examples, data operation requests may be to write data to ephemeral storage, which can be accomplished by sending the data operation requests and the associated data to a storage controller 416 at a storage resource 418 through an ephemeral data service 408, where the associated data can be subsequently written. In other examples, data operation requests may be for disaggregated blocks or objects, which are sent, along with any associated data, to the persistent memory resource 402 through either a front-end block service 410 or a front-end object service 412. The system can include a hot data storage service 414, which in some cases can be a software kernel module running on a host operating system (OS), virtual machine manager (VMM), or both. The hot data storage service 414 can facilitate communication between host software and the data service controller 422. Based on the policy configuration, the hot data storage service 414 can expose need-based persistent memory to the plurality of compute resources 404.

In response to receiving a data service operation request, the data service controller 422 can load one or more data service agents 426, depending on the nature of the requested data service operation. As has been described, various different data service agents are contemplated depending on the various data service operations implemented in a system. For example, the system can include a policy agent, which can be at least partially a software/firmware component that can perform secure policy provisioning, in some cases using internal SRAM. The policy agent can additionally be implemented according to various policy-based configurations, as is described more fully below. As another example, the system can include an error correction code (ECC) agent, which can be at least partially a software/firmware component that can perform ECC operations, in some cases using internal SRAM within the data service controller 422. As yet another example, the system can include an encryption agent, which can be at least partially a software/firmware component that can perform encryption based on various policy configurations, such as for example, geo-fence configurations, platform configurations, threat model configurations, and the like. In a further example, the system can include an analytics agent, which can be at least partially a software/firmware component that can perform various analytics, in some cases using internal SRAM. Nonlimiting examples of such analytics can include memory bandwidth analysis, memory traffic prioritization, ECC and/or encryption analytics, and the like. Various analytic observations can assist in cloud management and the fine tuning of cloud storage services logic, as well as patch deployment, cost analysis, etc. In yet another example, the system can include a data compression agent, which can be at least partially a software/firmware component that can perform data compression operations, in some cases using internal SRAM.

Once loaded, the data service agents 426 perform the data service operation on, in this example hot data 432, using an oob processor 428 within an oob environment 430. The data service controller 422 thus manages data service operations that would otherwise create a compute resource bottleneck, thus increasing the performance and efficiency of the system. Once the data service operation has been completed, the serviced data 434 can be sent to the storage controller 416 to be stored as ephemeral data.

In one example, the system can additionally include an administration controller 436 communicatively coupled to the persistent memory resource 402. The administration controller (or administration console) perform can provision data service agents 426 through the data service controller 422 to manage oob processor 428, the transfer of hot data to ephemeral storage dynamically and securely through the oob environment/channel. Additionally, the administration controller 436 can aggregate the various analytics, such as cloud storage and alert analytics for example, from a variety of systems running via secure oob channels, and can performs exploit mitigation patch deployment via independent of the host system. A data center distribution of workload in terms of specific compute resource needs for hot data memory can be correlated with the crowd-sourced analytics data for dynamic calibration by the administration controller 436 in order to meet any needed performance per watt/TCO savings.

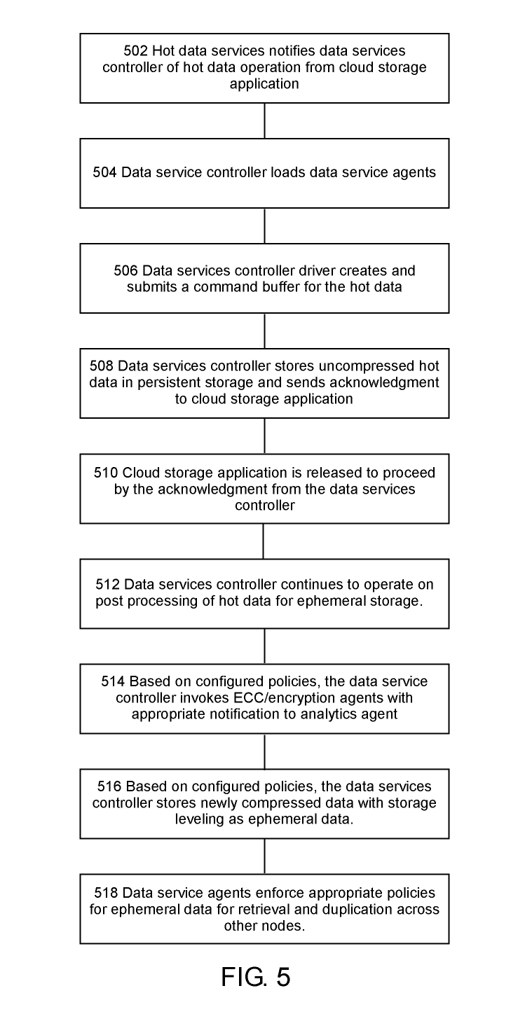

FIG. 5 shows one example of a method for performing data service operations on hot data. Once a data service operation to compress hot data is determined, 502 the hot data service notifies the data services controller of the hot data compression (or other operation) from a cloud storage application, and 504 the data service controller loads the appropriate data service agents. In one example, the data service operation can be a data compression operation, and as a result the data services controller would load one or more data service agents related to compression, such as a compression agent, a deduplication agent, or the like. A 506 data services controller driver creates and submits or otherwise initializes a command buffer for the hot data and 508 the data services controller stores the uncompressed hot data in the persistent system memory storage and sends an acknowledgment to the cloud storage application. Upon 510 receiving the acknowledgement from the data services controller, the cloud storage application is released to proceed and 512 the data services controller continues to operate on post processing of the hot data for ephemeral storage. In some examples, 514 based on configuration policies, the data service controller invokes ECC/encryption agents with appropriate notification to analytics agent, and in other examples 516 the data services controller stores newly compressed data with storage leveling as ephemeral data. Furthermore, 518 the data service agents enforce appropriate policies for ephemeral data for retrieval and duplication across other nodes.

As described above, a data service controller can load a data service agent or agents to perform data service operations at any level of the memory hierarchy, which in some cases can involve disaggregated memory resources. One nonlimiting implementation can involve a policy-based configuration of a policy agent. For example, a policy agent can be configured to select a memory hierarchy level to perform a given data service operation and facilitate the performance of the data service operation at the selected memory hierarchy level. The policy agent can thus implement a policy-based configuration to make memory hierarchy level selection decisions and thereby facilitate the performance of various data service operations on a memory hierarchy level that are data service operation-dependent, performance-dependent, resource-dependent, service level agreement (SLA)-dependent, data-dependent, priority-dependent, or the like.

A policy agent can also be configured to control various data- and performance-related operations. For example, a policy agent can be configured to control data operations in a data priority-based manner, such as by providing different instructions to different data priority groupings. In one implementation, the policy agent can direct lower priority data to be cached for delayed writing and higher priority data to be written immediately. In one implementation, the lower priority data can be written to the target memory resource as a batch-write during breaks between the writing of the higher priority data. In another implementation, the lower priority data can be interleaved into the write queue spaced to be written at a sufficiently low frequency to avoid negatively impacting the high priority data writes.

A policy agent can be configured to perform data operations for a variety of reasons. For example, a policy agent can move data, either within the same memory hierarchy level or between memory hierarchy levels. Data movement can include the aggregation or the disaggregation of data, which can include related data or unrelated data. In some cases, disaggregated data can be aggregated together in order to improve the processing performance of a data set. In other cases, aggregated data can be disaggregated in order to improve the performance of a memory resource by increasing free memory space, increase processing performance by sending portions of a data set to compute resources specialized or better able to process particular types of data, or the like. In one example, a policy agent may initiate an operation to move data from one memory resource to another memory resource or from a location within a memory resource to a different location within the same memory resource. Data can be moved for various reasons, including to improve performance, to make room for other data, to free up the memory resource to conserve power by minimizing memory maintenance tasks or to power down a portion or the entire memory resource, to spread a data set across multiple memory resources for security reasons, to wear-level memory resources, or the like. The entirety of the data can be relocated to a single new location or the data can be moved as part of an aggregation or disaggregation operation. In other words, in addition to merely moving data from one location to another location, data can be moved and aggregated with other data, whether related or unrelated, or moved to disaggregate the data.

### EXAMPLES

The following examples pertain to specific embodiments and point out specific features, elements, or steps that can be used or otherwise combined in achieving such embodiments.

In one example, there is provided a storage services control apparatus, comprising a compute resource interface configured to communicatively couple to a compute resource, a memory interface configured to communicatively couple to a memory resource, an out of band (oob) channel interface configured to communicatively couple to an oob channel, and a data service controller communicatively coupled to the oob channel interface. The data service controller is configured to identify a data service operation to be performed by the compute resource on data stored in the memory resource, load a data service agent configured to facilitate the data service operation, and perform the data service operation on the data to generate serviced data via the data service agent over the oob channel by an oob compute resource, thus freeing the compute resource from performing the data service operation.

In one example apparatus, the data service controller further configured to determine a location for storing the serviced data and send the serviced data to the determined location for storage.

In one example apparatus, the memory resource is included in a memory hierarchy level selected from the group consisting of a storage memory hierarchy level, a system memory hierarchy level, and a cache memory hierarchy level.

In one example apparatus, the data service controller further configured to perform the data service operation on the data in the memory resource in the memory hierarchy level to generate the serviced data, determine a destination memory hierarchy level to send the serviced data, determine a destination memory resource in the destination memory hierarchy level to send the serviced data, and send the serviced data to the destination memory resource.

In one example apparatus, the data service controller comprises a plurality of data service agents, each data service agent associated with a distinct data service operation.

In one example apparatus, the data service controller further configured to identify the data service agent associated with the data service operation from the plurality of data service agents.

In one example apparatus, the plurality of service agents includes an analytic agent configured to conduct memory bandwidth analysis, prioritize memory traffic, analyze one or more other service agents, or a combination thereof.

In one example apparatus, the plurality of service agents includes an error correction code agent to perform error correction code operations on the data.

In one example apparatus, the plurality of service agents includes an encryption agent to perform encryption and decryption operations on the data.

In one example apparatus, the plurality of service agents includes a policy agent to implement a policy-based configuration.

In one example apparatus, the policy-based configuration includes a configuration selected from the group consisting of a data priority policy, a memory hierarchy level policy, a data disaggregation/aggregation policy, a memory resource maintenance policy, a power usage policy, and combinations thereof.

In one example apparatus, the plurality of service agents includes a compression agent.

In one example apparatus, the compression agent is configured to access the data in the memory resource through the oob channel and perform a compression process on the data using the oob compute resource to generate compressed data.

In one example apparatus, the compression agent is further configured to move the compressed data to a different memory resource.

In one example apparatus, the compression agent is a deduplication agent.

In one example apparatus, the memory resource is persistent, write-in-place, byte-addressable system memory.

In one example apparatus, the memory resource includes a three-dimensional (3D) phase-change memory medium having a cross-point array architecture.

In one example apparatus, the oob channel includes a channel selected from the group consisting of trusted execution environments (TEEs), system management environments, isolated segments of a data bus, communication fabric channels, and combinations thereof.

In one example, there is provided a network system node comprising a persistent system memory resource, an out of band (oob) channel, and a data service controller communicatively coupled to the oob channel. The data service controller is configured to receive a plurality of data service operation requests for a plurality of data sets in the persistent system memory resource each associated with a plurality of applications running on a plurality of compute resources, load a set of data service agents to perform each data service operation of the plurality of data service operation requests, and perform each data service operation on each data set to generate a plurality of serviced data sets via the associated set of data service agent over the oob channel by an oob compute resource, thus freeing each of the plurality of compute resources from performing the associated data service operation.

In one example network system node, the data service controller comprises a plurality of data service agents, each data service agent associated with a distinct data service operation.

In one example network system node, the data service controller further configured to identify the set of data service agents associated with each data service operation from the plurality of data service agents.

In one example network system node, the plurality of service agents includes an analytic agent configured to conduct memory bandwidth analysis, prioritize memory traffic, analyze one or more other service agents, or a combination thereof.

In one example network system node, the plurality of service agents includes an error correction code agent to perform error correction code operations on the data.

In one example network system node, the plurality of service agents includes an encryption agent to perform encryption and decryption operations on the data.

In one example network system node, the plurality of service agents includes a policy agent.

In one example network system node, the plurality of service agents includes a compression agent.

In one example network system node, the compression agent is configured to access each data set in the persistent system memory resource through the oob channel and perform a compression process on each data set using the oob compute resource to generate a plurality of compressed data sets.

In one example network system node, the compression agent is further configured to move each compressed data set to a different memory resource.

In one example network system node, the compression agent is a deduplication agent.

In one example network system node, the persistent system memory resource is write-in-place, byte-addressable system memory.

In one example network system node, the persistent system memory resource includes a three-dimensional (3D) phase-change memory medium having a cross-point array architecture.

In one example network system node, the oob channel includes a channel selected from the group consisting of trusted execution environments (TEEs), system management environments, isolated segments of a data bus, communication fabric channels, and combinations thereof.

In one example, there is provided a method for performing data service operations, comprising receiving a request at a data service controller to perform a data service operation on data associated with a primary compute resource and stored in a persistent system memory resource, loading at least one data service agent to perform the data service operation, releasing the primary compute resource from performing the data service operation, and performing the data service operation with the at least one data service agent using an out of band (oob) compute resource over an oob channel.

In one example method, the at least one data service agent is elected from a plurality of data service agents each specialized to perform a different data service operation.

In one example method, the data service operation is data compression operation, the data service agent is a compression agent, and the data is hot data, wherein the method further comprises accessing the hot data in the primary memory resource through the oob channel and performing the data compression operation on the hot data using the oob compute resource to generate compressed data.

In one example, the method further comprises moving the compressed data to a different memory resource.

In one example method, the compression agent is a deduplication agent, and the method further comprises performing the data compression operation by deduplicating the hot data using the deduplication agent.

In one example method, the hot data is a disaggregated portion of a hot data set.

What is claimed is:

1. A storage services control apparatus, comprising:
a compute resource interface configured to communicatively couple to a compute resource;
a memory interface configured to communicatively couple to a memory resource;
an out of band (oob) channel interface configured to communicatively couple to an oob channel;
a data service controller communicatively coupled to the oob channel interface, the data service controller configured to:
identify a data service operation to be performed by the compute resource on data stored in the memory resource;
load a data service agent configured to facilitate the data service operation; and
perform the data service operation on the data to generate serviced data via the data service agent over the oob channel by an oob compute resource, thus freeing the compute resource from performing the data service operation.

2. The apparatus of claim 1, the data service controller further configured to:
determine a location for storing the serviced data; and
send the serviced data to the determined location for storage.

3. The apparatus of claim 1, wherein in the data service controller comprises a plurality of data service agents, each data service agent associated with a distinct data service operation.

4. The apparatus of claim 3, the data service controller further configured to identify the data service agent associated with the data service operation from the plurality of data service agents.

5. The apparatus of claim 3, wherein the plurality of service agents includes an analytic agent, an error correction code agent, an encryption agent, a policy agent, or any combination thereof.

6. The apparatus of claim 3, wherein the plurality of service agents includes a compression agent configured to:
access the data in the memory resource through the oob channel; and
perform a compression process on the data using the oob compute resource to generate compressed data.

7. The apparatus of claim 6, wherein the compression agent is further configured to move the compressed data to a different memory resource.

8. The apparatus of claim 6, wherein the compression agent is a deduplication agent.

9. The apparatus of claim 1, wherein the memory resource is persistent, write-in-place, byte-addressable system memory.

10. The apparatus of claim 9, wherein the memory resource includes a three-dimensional (3D) phase-change memory medium having a cross-point array architecture.

11. The apparatus of claim 1, wherein the oob channel includes a channel selected from the group consisting of trusted execution environments (TEEs), system management environments, isolated segments of a data bus, communication fabric channels, and combinations thereof.

12. A network system node, comprising:
a persistent system memory resource;
an out of band (oob) channel;
a data service controller communicatively coupled to the oob channel, the data service controller configured to:
receive a plurality of data service operation requests for a plurality of data sets in the persistent system memory resource each associated with a plurality of applications running on a plurality of compute resources;
load a set of data service agents to perform each data service operation of the plurality of data service operation requests; and
perform each data service operation on each data set to generate a plurality of serviced data sets via the associated set of data service agent over the oob channel by an oob compute resource, thus freeing each of the plurality of compute resources from performing the associated data service operation.

13. The network system node of claim 12, wherein the data service controller comprises a plurality of data service agents, each data service agent associated with a distinct data service operation.

14. The network system node of claim 14, the data service controller further configured to identify the set of data service agents associated with each data service operation from the plurality of data service agents.

15. The network system node of claim 14, wherein the plurality of service agents includes a compression agent configured to:
access each data set in the persistent system memory resource through the oob channel; and
perform a compression process on each data set using the oob compute resource to generate a plurality of compressed data sets.

16. The network system node of claim 15, wherein the compression agent is further configured to move each compressed data set to a different memory resource.

17. The network system node of claim 12, wherein the persistent system memory resource is write-in-place, byte-addressable system memory.

18. The network system node of claim 17, wherein the persistent system memory resource includes a three-dimensional (3D) phase-change memory medium having a cross-point array architecture.

19. The network system node of claim 12, wherein the oob channel includes a channel selected from the group consisting of trusted execution environments (TEEs), system management environments, isolated segments of a data bus, communication fabric channels, and combinations thereof.

20. A method for a method for performing data service operations, comprising:
receiving a request at a data service controller to perform a data service operation on data associated with a primary compute resource and stored in a persistent system memory resource;
loading at least one data service agent to perform the data service operation;
releasing the primary compute resource from performing the data service operation; and
performing the data service operation with the at least one data service agent using an out of band (oob) compute resource over an oob channel.

21. The method of claim 20, wherein the at least one data service agent is elected from a plurality of data service agents each specialized to perform a different data service operation.

22. The method of claim 20, wherein the data service operation is data compression operation, the data service agent is a compression agent, and the data is hot data, wherein the method further comprises:
accessing the hot data in the primary memory resource through the oob channel; and
performing the data compression operation on the hot data using the oob compute resource to generate compressed data.

23. The method of claim 22, wherein the method further comprises moving the compressed data to a different memory resource.

24. The method of claim 22, wherein the compression agent is a deduplication agent, and the method further comprises performing the data compression operation by deduplicating the hot data using the deduplication agent.

25. The method of claim 22, wherein the hot data is a disaggregated portion of a hot data set.
